(19) United States
(12) Patent Application Publication
(10) Pub. No.: US 2024/0162789 A1
(43) Pub. Date: May 16, 2024

(54) DETERMINATION OF A MOTOR CURRENT IN A MOTOR VEHICLE

(71) Applicant: ZF Friedrichshafen AG, Friedrichshafen (DE)

(72) Inventors: Matthias Selig, Friedrichshafen (DE); Kevin Heimburger, Engen (DE); Tobias Andersch, Hahnbach (DE); Benjamin Brose, Tettnang (DE); Markus Eißner, Eschenbach i. Opf. (DE); Tobias Eichermüller, Amberg (DE)

(73) Assignee: ZF Friedrichshafen AG, Friedrichshafen (DE)

(21) Appl. No.: 18/510,334

(22) Filed: Nov. 15, 2023

(30) Foreign Application Priority Data
Nov. 15, 2022 (DE) 102022212096.5

(51) Int. Cl. H02K 11/27; G01R 15/20; G01R 19/00; H02K 3/50

(52) U.S. Cl. CPC H02K 11/27; G01R 15/202; G01R 19/0092; H02K 3/50; B60L 50/00

(57) ABSTRACT

A sensor assembly for the determination of an electric current which flows through an electric drive machine of a motor vehicle comprises a busbar through which the electric current flows, and a first and a second magnetic field sensor for determining magnetic fields in the region of the busbar, wherein the magnetic field sensors are attached so that they are spaced apart from one another in a direction perpendicular to the direction of extent of the busbar.

### CROSS-REFERENCE TO RELATED APPLICATION

This application claims priority to German Application No. DE 10 2022 212 096.5, filed on Nov. 15, 2022, the entirety of which is hereby fully incorporated by reference herein.

### FIELD

The present invention relates to the determination of an electric current flowing through an electric drive motor of a motor vehicle.

### BACKGROUND

A motor vehicle comprises an electric drive motor which is powered from an onboard energy store. The drive motor can be designed, for example, as a permanently excited synchronous machine (PSM) and can require three phase-shifted alternating voltages, whilst the energy store supplies a direct voltage. The necessary conversion can be effected by a converter. In order to control a rotational speed of the drive motor or a torque supplied by it, the converter can vary frequencies or amplitudes of the supplied voltages. For this purpose, the electric current flowing through the drive motor needs to be determined with a high degree of accuracy.

In order to determine such a current, a magnetic field which is formed about a busbar through which the current flows can be measured. To do this, the magnetic field in the region of the busbar is usually shaped and collected by means of a metal core in order to be measured by means of a cost-effective sensor. However, such cores require a large amount of structural space and are relatively heavy. Material and handling costs can be considerable.

One object on which the present disclosure is based consists in providing an improved technique for the determination of a motor current in a motor vehicle. The invention achieves this object by means of the subjects of the present disclosure. The present disclosure also includes preferred embodiments.

According to one aspect of the present disclosure, a sensor assembly for the determination of an electric current which flows through an electric drive machine of a motor vehicle comprises a busbar through which the electric current flows; and a first and a second magnetic field sensor for determining magnetic fields in the region of the busbar. The magnetic field sensors are here attached so that they are spaced apart from one another in a direction perpendicular to the direction of extent of the busbar.

High currents, which can be in the region of approximately 1000 amperes on a conventional car, flow through the drive machine. A flowing current induces in the region of the busbar a magnetic field with field lines which run perpendicularly to the direction of extent of the busbar or to the direction of flow of the electric current (the “right hand grip rule”). The magnetic field sensors are preferably attached symmetrically with respect to a center line or the same distance away from outer edges of the busbar. Magnetic fields, measurable by virtue of the flow of current, at the two magnetic field sensors can then have the same magnitude but a different sign. An external magnetic field can, however, influence the two magnetic field sensors in the same way such that they can be differentiated from each other. The current flowing through the busbar can therefore be determined simply and accurately.

A magnetic core for shaping or concentrating magnetic field lines can be unnecessary. The magnetic field sensors can be constructed simply and cost-effectively. As a whole, the sensor assembly can be compact and light. Associated cost advantages can be exploited.

In an embodiment, the magnetic field sensors are comprised of an integrated circuit (IC). The integrated circuit can be made available in a cost-effective fashion as a standard component. The IC can be robust with respect to environmental influences in the region of a motor vehicle by virtue of conventional encapsulation in a semiconductor housing. For example, the IC can be resistant to vibrations, dust, moisture, or aggressive media such as oil or acid. The IC can moreover comprise an internal circuit for the differential evaluation of the magnetic fields determined by means of the two magnetic field sensors. A measured value for the total determined magnetic field can be supplied in a preprocessed or amplified form.

It is further disclosed that the sensor assembly comprises a processing device for determining the electric current on the basis of a difference between the magnetic fields determined by means of the magnetic field sensors. The processing device can be a constituent part of the IC or be provided as a dedicated device. In one embodiment, the integrated circuit supplies a determined measured value in digital form. The transmission of the digital value on a line can be less disrupted by the magnetic field. In another embodiment, the processing device converts analog sensor values into digital values and supplies these at an interface. At the same time, the sensor values can be processed, for example by a linear combination or amplification.

The magnetic field sensors can advantageously be designed as Hall effect sensors. A wide range of such sensors can be available cost-effectively and are frequently designed as an integrated circuit. An achievable measurement accuracy can be sufficient in the specified measurement system.

In a further embodiment, the busbar has a relieved portion in the region of the magnetic field sensors. The relieved portion can reduce a cross-section of the busbar and the magnetic field sensors can be situated in the region of the relieved portion. In a preferred embodiment, the magnetic field sensors are situated next to a constriction, or between two constrictions, on one side of the busbar. In particular when a relative spacing between the magnetic field sensors is constant, for example because the sensors are accommodated in an integrated circuit, they can be brought closer to lateral boundaries of the busbar by the constriction such that measurable magnetic fields are stronger. The constriction can simply shape and locally amplify the magnetic field acting in the region of the magnetic field sensors. An achievable measurement accuracy of the sensor assembly can be further increased as a result.

In a further embodiment, the busbar comprises a thermoplastic cover, wherein the magnetic field sensors are attached in form-fitting fashion to the cover. In particular, the busbar can be covered with a thermoplastic material, embedded in the latter or overmolded with the latter. Adhesion of the thermoplastic material to the busbar can be very good. The plastic can retain its shape in the case of expected operating temperatures on board the motor vehicle. The magnetic field sensors can be well positioned on the cover and connected rigidly thereto such that a position of a magnetic field sensor relative to the busbar does not change after mounting.

In a further variant, a plurality of integrated circuits described herein are attached to a printed circuit board, wherein the printed circuit board is attached in form-fitting fashion to the cover. The sensors can be positioned and oriented precisely on the printed circuit board, for example by means of a pick-and-place machine, and relative spacings between the integrated circuits can be kept constant by the printed circuit board. The printed circuit board can be easily attached to one or more busbars as a component which can be handled separately. A processing device for processing sensor values of the sensors can be attached to the printed circuit board. An interface for supplying processed or unprocessed sensor values can also be attached to the printed circuit board. The processing device can process sensor values of a plurality of sensors and determine a plurality of currents.

In a particular embodiment, a plurality of busbars are provided which each transport a current flowing through the electric drive machine. The busbars can have a common cover to which the printed circuit board can be attached. The electric drive machine can comprise three phases and the sensor assembly can be configured to determine two or three currents. In one embodiment, two currents can be determined on the basis of sensor values and the third can be determined from the sum of the other two.

In a particular embodiment, the magnetic field sensors are, or the printed circuit board is, heat-staked to the cover. A position of the magnetic field sensors relative to a busbar can thus be kept constant with a high degree of accuracy. Just a small change in the spacing or the orientation of a magnetic field sensor or integrated circuit from the busbar can lead to a significant error in the determined current. In one embodiment, a change in the spacing by approximately 20 μm can constitute an error of approximately 1%. The accurate and permanent fixing of the magnetic field sensors relative to the busbar can contribute to minimizing the measurement error.

According to a further aspect of the present disclosure, a connection apparatus for a motor vehicle comprises a busbar for guiding an electric current to an electric drive machine, and a sensor assembly described herein. The connection apparatus can also comprise a plurality of, in particular three, busbars and two or three sensor assemblies described herein. The connection apparatus further preferably also comprises a processing device described herein. The connection apparatus can be supplied as a component which can be handled separately. An electrical connection between an electric drive machine and a converter on board a motor vehicle can be produced by means of the connection apparatus.

According to a further aspect of the present disclosure, a drive device for a motor vehicle comprises a connection apparatus described herein and an electric drive machine or a converter for supplying a current flowing through the electric drive machine. The drive device can comprise an axle drive and optionally has a gearbox. In a further embodiment, the drive device is designed as a hybrid gearbox and comprises an input shaft which can be connected to a further drive machine, in particular to an internal combustion engine.

According to yet another aspect of the present disclosure, a motor vehicle comprises a drive device described herein or a connection apparatus described herein. The motor vehicle can in particular comprise a car, a truck, or a bus.

According to a further aspect of the present disclosure, a method for producing a sensor assembly for the determination of an electric current which flows through an electric drive machine of a motor vehicle comprises steps of attaching two magnetic field sensors to a busbar through which the electric current flows, wherein the magnetic field sensors are attached in such a way that they are spaced apart from each other in a direction perpendicular to the direction of extent of the busbar, wherein the busbar has a thermoplastic cover and the magnetic field sensors are heat-staked to the cover.

A sensor assembly described herein which can advantageously be used on a motor vehicle can in this way be supplied simply and cost-effectively. It is preferred that a sensor assembly is calibrated individually before it is used to determine a current on board a motor vehicle. To do this, a predetermined current can be induced by the busbar and a supplied measured value adapted in such a way that it corresponds sufficiently accurately to the flowing current.

The present disclosure will now be described more accurately with reference to the attached Figures.

### BRIEF DESCRIPTION OF THE DRAWINGS

FIG. 1 illustrates a sensor assembly;

FIGS. 2 and 3 each illustrate a sensor assembly on a drive device;

FIG. 4 illustrates a printed circuit board with sensors for a sensor assembly;

FIG. 5 illustrates a longitudinal section through a sensor assembly on a drive device;

FIG. 6 illustrates a flow diagram of a method for producing a sensor assembly; and

FIGS. 7 and 8 illustrate further embodiments of sensor assemblies.

### DETAILED DESCRIPTION

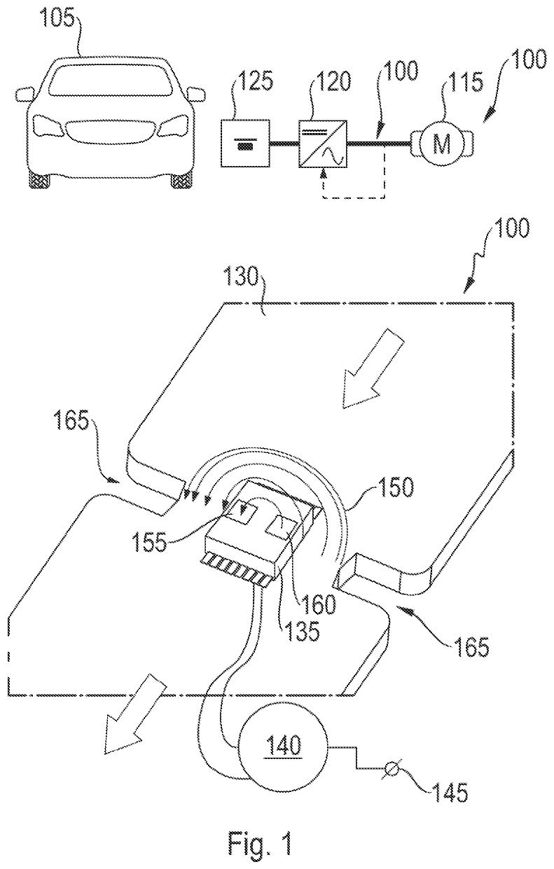

FIG. 1 shows a sensor assembly 100 for use on board a motor vehicle 105. The motor vehicle 105 comprises an electric drive train 110 with an electric drive machine 115. The drive machine 115 can be connected by means of the sensor assembly 100 to a converter 120 which is fed from an energy store 125. The sensor assembly 100 is configured to determine an electric current flowing through the drive machine 115. The converter 120 can use the determined current in order to control the electric drive machine 115.

The sensor assembly 100 comprises a busbar 130, to which an integrated circuit 135 is attached, and a processing device 140. In one embodiment, the processing device 140 is included partially or completely in the integrated circuit 135. A determined current which flows through the busbar 130 can be supplied externally by means of an interface 145.

Purely by way of example, it will be assumed for the present description that an electric current flows through the busbar 130 in the direction of the block arrows from top right to bottom left in FIG. 1. A magnetic field which is symbolized by exemplary field lines 150 thus results. The integrated circuit 135 comprises a first magnetic field sensor 155 and a second magnetic field sensor 160 which are spaced apart from each other horizontally.

Each magnetic field sensor 155, 160 can have a sensitive semiconductor surface for exploiting the Hall effect. The integrated circuit 135 is attached to the busbar 130 in such a way that a connecting line between the magnetic field sensors 155 and 160 runs perpendicular to a direction of extent of the busbar 130 and to a direction of flow of the electric current. It is further preferred that the magnetic field sensors 155, 160 are attached symmetrically with respect to the busbar 130 such that respective spacings between a magnetic field sensor 155, 160 and a lateral boundary of the busbar 130 are of the same size.

By virtue of the assembly of magnetic field sensors 155, 160, a magnetic field can be determined which is induced by the flowing current in the busbar 130, with the same magnitudes but different signs. An assembly in the integrated circuit 135, or the processing device 140, can determine a magnetic field thereon which is induced by the electric current. An external magnetic field which is applied to the two magnetic field sensors 155, 160 with the same magnitude and the same sign can be insignificant here. A value indicative of the determined magnetic field or the determined electric current can be output at the interface 145.

It is preferred that the busbar 130 has at least one relieved portion 165 in order to locally reduce a spacing between a magnetic field sensor 155, 160 and a lateral boundary of the busbar 130. In the embodiment illustrated, two relieved portions 165 of the same size are provided which are situated opposite each other. The relieved portions 165 are situated along a connecting line between the magnetic field sensors 155 and 160. A constriction or narrowing of the busbar 130 in the region of the magnetic field sensors 155, 160 is created as a result.

A current density can be increased in the region of the constriction. The busbar 130 can be heated in this region by the flowing current, wherein an additional heat output of just a few watts has to be assumed in the case of the usual dimensions. The heating can be insignificant compared with other heat sources, in particular the electric drive machine 115. An existing cooling concept can be used to dissipate resulting thermal energy from the busbar 130.

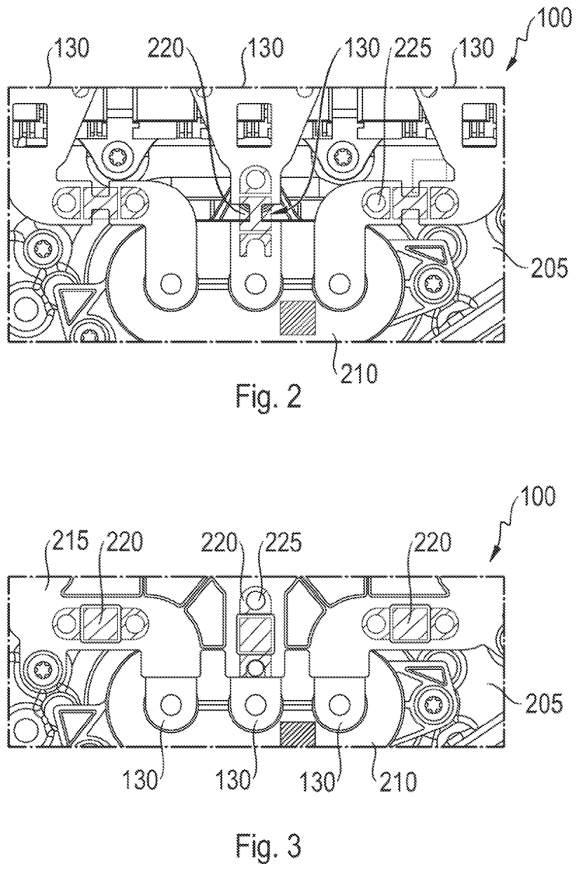

FIGS. 2 and 3 each show a sensor assembly 100 on a drive device 205 which can be part of the drive train 110. In the present case, the sensor assembly 100 is attached to a housing of the drive device 205 which accommodates an electrical connection 210 for connection to the electric drive machine 115. The electrical connection 210 is connected to three busbars 130 and is illustrated uninsulated in FIG. 2 and enclosed by a cover 215 in FIG. 3.

The cover 215 preferably comprises a plastic, more preferably a thermoplastic, and can be molded or sprayed around a busbar 130. Exemplary contours of an accommodating geometry 220, which in each case represent a space in which a pair of magnetic field sensors 155, 160 or an integrated circuit 135 can be accommodated, are indicated in each case in the region of a pair of relieved portions 165. One or more pins 225, which extend from the plane of the drawing in the direction of the viewer and are made from the same material as the cover 215, can preferably be formed in the region of an accommodating geometry 220.

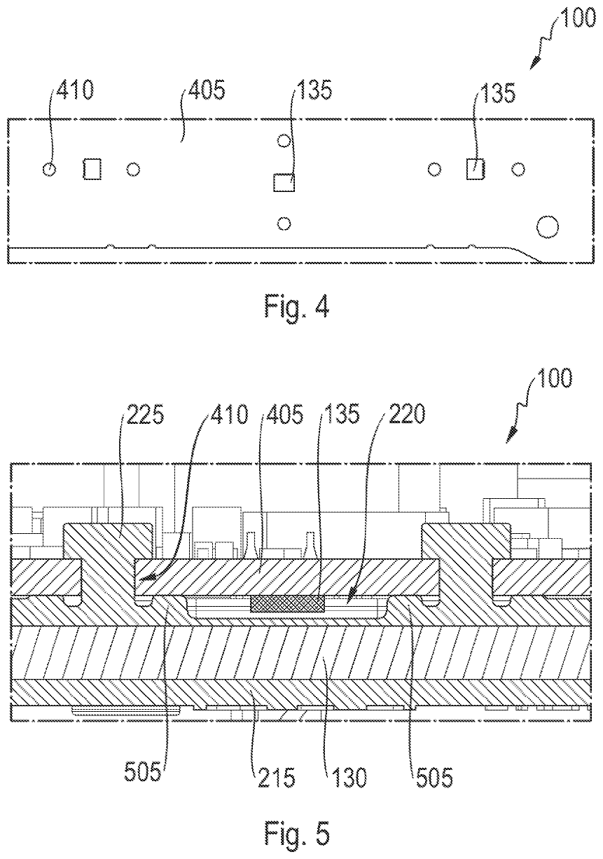

FIG. 4 shows an exemplary printed circuit board 405. Three integrated circuits 135 are, by way of example, attached to the printed circuit board 405. The integrated circuits 135 are preferably surface mounted devices (SMD) and can comprise, for example, a small outline (SO) housing. Relieved portions 410 are provided to accommodate the pins 225. A processing device 140 is optionally attached to the printed circuit board 405. The interface 145 can be designed, for example, in the form of a plug connector.

FIG. 5 shows a longitudinal section through a sensor assembly 100 on a drive device 205. The illustration corresponds to those in FIGS. 2 to 4. The printed circuit board 405 is placed on the cover 215 of a busbar 130 such that the pins 225 are guided through corresponding relieved portions 410. Upper ends of the pins 225 are preferably deformed by means of heat staking into a mushroom shape so that the printed circuit board 405 is retained securely on the cover 215 and the busbar 130 in all directions.

The integrated circuit 135 is situated on a side of the printed circuit board 405 facing the busbar 130. In this region, the accommodating geometry 220 comprises a depression for accommodating the integrated circuit 135. A spacing between the printed circuit board 405 and the busbar 130 can be determined by support elements 505 which can be formed on the cover 215. Support elements 505 are preferably situated in each case so that they are adjacent to pins 225.

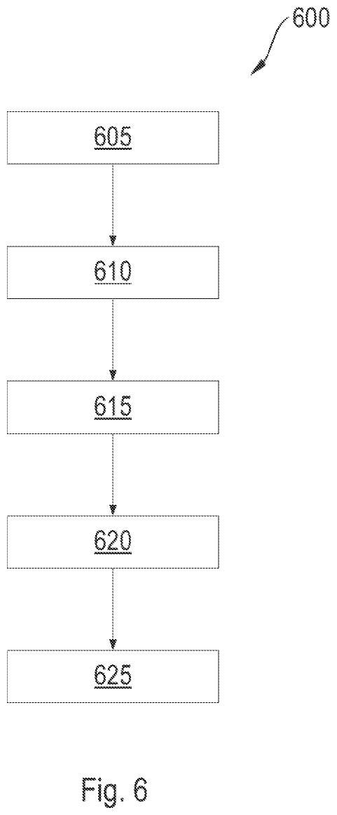

FIG. 6 shows a flow diagram of a method 600 for producing a sensor assembly 100. In a step 605, a busbar 130 is provided or supplied with a cover 215. The cover 215 can be formed on the busbar 130, for example, by overmolding or injection molding.

In a step 610, a pair of magnetic field sensors 155, 160 are attached to a printed circuit board 405. The magnetic field sensors 155, 160 are preferably included in an integrated circuit 135 which can be soldered to traces on a surface of the printed circuit board 405.

In a step 615, the printed circuit board 405 is attached to the cover 215. To do this, pins 225 are inserted into corresponding relieved portions 410.

In a step 620, the pins 225 can be heat-staked. To do this, the printed circuit board 405 can be pushed onto the busbar 130, whilst upper ends of the pins 225 are first heated and then pushed against the printed circuit board 405 by means of a punch such that the pins 225 deform and radially expand at their upper ends. Heads which retain the printed circuit board 405 on the cover 215 can thus be formed on the pins 225.

In an optional step 625, the sensor assembly 100 can be calibrated individually. To do this, a predetermined electric current can be induced by the busbar 130 and the processing of the magnetic fields detected by means of the magnetic field sensors 155, 160 can be adapted such that a supplied measured value corresponds sufficiently accurately to the flowing current.

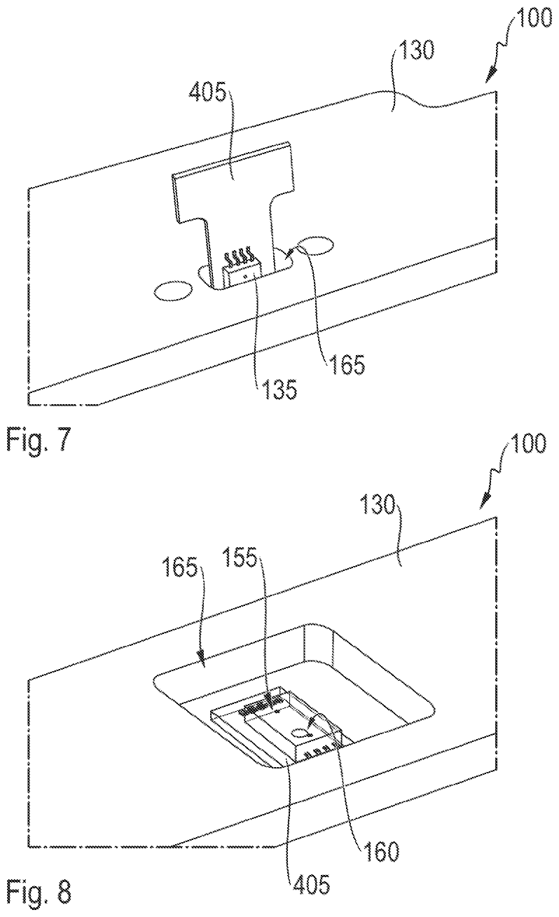

FIG. 7 shows a further embodiment of a sensor assembly 100. The relieved portion 165 here runs vertically through the busbar 130 such that the relieved portion 165 is surrounded horizontally on all sides by material of the busbar 130. A printed circuit board 405 is plugged into the relieved portion 165 in a vertical direction. An integrated circuit 135 with magnetic field sensors 155, 160 which are offset vertically such that one of them is toward the viewer and the other is remote from them is attached to the printed circuit board 405.

FIG. 8 shows yet another embodiment of a sensor assembly 100. The relieved portion 165 is, as in the illustration in FIG. 7, here situated in the material of the busbar 130 such that the relieved portion 165 is closed horizontally on all sides. The integrated circuit 135 is, however, not oriented as in FIG. 7 and instead as in FIG. 1. Included magnetic field sensors 155, 160 are spaced apart from each other perpendicularly to a direction of extent of the busbar 130. The integrated circuit 135 can be attached to the printed circuit board 405 which can be situated outside or in some places inside the relieved portion 165.

### REFERENCE SIGNS

100 sensor assembly
105 motor vehicle
110 electric drive train
115 electric drive machine
120 converter
125 energy store
130 busbar
135 integrated circuit
140 processing device
145 interface
150 field lines
155 first magnetic field sensor
160 second magnetic field sensor
165 relieved portion
205 drive device
210 electrical connection
215 cover
220 accommodating geometry
225 pin
405 printed circuit board
410 relieved portion
505 support element
600 method
605 supply busbar with cover
610 attach pair of sensors to printed circuit board
615 attach printed circuit board to cover, insert bolts in relieved portions
620 heat staking
625 calibrate individually

1. A sensor assembly for the determination of an electric current which flows through an electric drive machine of a motor vehicle, the sensor assembly comprising:
a busbar configured such that the electric current flows therethrough; and
a first and a second magnetic field sensor configured to determine magnetic fields in a region of the busbar,
wherein the first and second magnetic field sensors are attached so that they are spaced apart from one another in a direction perpendicular to a direction of extent of the busbar.

2. The sensor assembly according to claim 1, wherein the first and second magnetic field sensors are included in an integrated circuit.

3. The sensor assembly according to claim 1, comprising:
a processing device configured to determine the electric current on a basis of a difference between the magnetic fields determined detected by the first and second magnetic field sensors.

4. The sensor assembly according to claim 1, wherein the first and second magnetic field sensors are Hall effect sensors.

5. The sensor assembly according to claim 1, wherein the busbar has a relieved portion in a region of the first and second magnetic field sensors such that a cross-section of the busbar is reduced, and
wherein the first and second magnetic field sensors are situated in a region of the relieved portion.

6. The sensor assembly according to claim 1, wherein the busbar has a thermoplastic cover, and
wherein the first and second magnetic field sensors are attached in form-fitting fashion to the thermoplastic cover.

7. The sensor assembly according to claim 6,
wherein a plurality of integrated circuits are attached to a printed circuit board, and
wherein the printed circuit board is attached in form-fitting fashion to the thermoplastic cover.

8. The sensor assembly according to claim 6, wherein the first and second magnetic field sensors are, or the printed circuit board is, heat-staked to the thermoplastic cover.

9. A connection apparatus for a motor vehicle, comprising:
a busbar configured to guide an electric current to an electric drive machine; and
the sensor assembly according to claim 1.

10. A drive device for a motor vehicle, comprising:
the connection apparatus according to claim 9; and
an electric drive machine or a converter configured to supply a current flowing through the electric drive machine.

11. A motor vehicle comprising:
the drive device according to claim 10.

12. A method for producing a sensor assembly for the determination of an electric current which flows through an electric drive machine of a motor vehicle, the method comprising:
attaching two magnetic field sensors to a busbar through which the electric current flows;
attaching the two magnetic field sensors in such a way that they are spaced apart from each other in a direction perpendicular to the direction of extent of the busbar; and
heat-staking the two magnetic field sensors to a thermoplastic cover of the busbar.

13. The method according to claim 12, comprising:
including the two magnetic field sensors in an integrated circuit.

14. The method according to claim 12, comprising:
providing a processing device configured to determine the electric current on a basis of a difference between the magnetic fields determined detected between the two magnetic field sensors.

15. The method according to claim 12, wherein the two magnetic field sensors are Hall effect sensors.

16. The method according to claim 12, comprising:
providing the busbar such that it has a relieved portion in a region of the two magnetic field sensors such that a cross-section of the busbar is reduced, and
situating the two magnetic field sensors in a region of the relieved portion.

17. The method according to claim 12, comprising:
attaching a plurality of integrated circuits to a printed circuit board; and
attaching the printed circuit board in form-fitting fashion to the thermoplastic cover.

18. The method according to claim 12, comprising:
heat-staking the printed circuit board to the thermoplastic cover.
